(19) United States
(12) Patent Application Publication
(10) Pub. No.: US 2002/0145147 A1
(43) Pub. Date: Oct. 10, 2002

(54) Light emitting diode and manufacturing method thereof

(76) Inventors: Shu-Woei Chiou, Miaoli (TW); Holin Chang, Kaohsiung (TW); Tzer-Perng Chen, Hsingchu (TW); Chih-Sung Chang, Taipei (TW)

Correspondence Address: BAKER & BOTTS, 30 ROCKEFELLER PLAZA, NEW YORK, NY, 10112

(21) Appl. No.: 10/022,055

(22) Filed: Dec. 18, 2001

(30) Foreign Application Priority Data
Apr. 9, 2001 (TW) 90108478

(51) Int. Cl. H01L 33/00; H01L 31/12; H01L 27/15

(52) U.S. Cl. 257/79

(57) ABSTRACT

A light emitting diode (LED) is disclosed. The problem of an emitting light absorbed by a substrate can be prevented by using a bragg reflector layer with high reflectivity. The present invention provides a high reflectivity bragg reflector layer to reflect the light generated from LED, which comprises high aluminum-contained AlGaAs/AlGaInP layers or high aluminum-contained AlGaAs/low aluminum-contained AlGaInP layers, formed on the substrate before the vertically stacked epitaxial structure of the light emitting diode is formed. Due to the higher oxidation ability of the high aluminum-contained AlGaAs layers and the lower refraction index of the oxide thereof, the wavelength reflected by the bragg reflector layer can cover a wider spectrum and the reflectivity thereof is very high. Since the oxidized AlGaAs layer is an electrical insulator, the present invention provides electrodes located on the same side of the light emitting diode. Thus, the internal resistance of the light emitting diode can be decreased, and the electro-optics transferring rate can be increased. In this way, the light emitting diode having the structure as described above has a higher light efficiency than the conventional light emitting diode.

### FIELD OF THE INVENTION

The present invention relates to a light emitting diode (LED) epitaxial structure and a manufacturing method thereof, and more particularly to a bragg reflector layer with high reflectivity used in the light emitting diode chip structure for increasing the light efficiency and the manufacturing method thereof.

### Background of the Invention

The conventional AlGaInP light emitting diode, as shown in FIG. 1, has a double heterostructure (DH), which is composed of an n-type (AlₓGa₁₋ₓ)_{0.5}In_{0.5}P lower cladding layer 4 with a Al dosage of about 70%˜100%, formed on an n-type GaAs substrate 3, a (AlₓGa₁₋ₓ)_{0.5}In_{0.5}P active layer 5, a p-type (AlₓGa₁₋ₓ)_{0.5}In_{0.5}P upper cladding layer 6 with a Al dosage 70%˜100% and a p-type current spreading layer 7 made of GaP, GaAsP or AlGaAs having high energy gap and high carrier concentration. The emitting wavelength of the light emitting diode structure can be changed by changing the composition of the active layer so as to generate a wavelength from red light of 650 nm in wavelength t to pure green of 555 nm. One disadvantage of the conventional light emitting diode is that, when the light generated by the active layer is emitted deep to the GaAs substrate, the light will be absorbed by the GaAs substrate since the GaAs substrate has a lesser energy gap. Accordingly, the performance of the light emitting diode will be greatly reduced.

There are some conventional light emitting diode technologies have been disclosed in order to prevent the light from being absorbed by the substrate. However, these conventional technologies still have some disadvantages and limitations. For example, Sugawara et al. disclosed a method, which has been published in Appl. Phys Lett. Vol. 61, 1775-1777 (1992), that a distributed bragg reflector (DBR) layer is added to the GaAs substrate so as to reflect the light ejected to the GaAs substrate thereby decreasing the light absorbed by the GaAs substrate. However, because the DBR layer can only effectively reflect the light that is in the proximity of the direction vertical to the GaAs substrate, the range of the wavelength of reflected light is very narrow, so that the addition of DBR layer does not have much effect.

Kish et al. disclosed a wafer-bonded transparent-substrate (TS) (AlₓGa₁₋ₓ)_{0.5}In_{0.5}P/GaP light emitting diode [Appl. Phys Lett. Vol. 64, No. 21, 2839 (1994); Very high-efficiency semiconductor wafer-bonded transparent-substrate (AlₓGa₁₋ₓ)_{0.5}In_{0.5}P/GaP]. This TS AlGaInP light emitting diode is fabricated by growing a very thick (about 50 μm) p-type GaP window layer using vapor phase epitaxy (VPE). After bonding, the n-type GaAs substrate is selectively removed by using conventional chemical etching techniques. The exposed n-type lower cladding layers subsequently are bonded to about 8-10 mil thick n-type GaP substrate. Since the wafer-bonded technology is to directly bond two III-IV compound semiconductors together, the process has to be performed under the condition of high temperature and high pressure for quite a period of time. The TS AlGaInP light emitting diode thus formed can exhibit the brightness that is two times greater than the conventional absorbing substrate (AS) AlGaInP light emitting diode. However, the fabrication process of TS AlGaInP light emitting diode is too complicated. Therefore, it is difficult to manufacture these TS AlGaInP light emitting diodes with high yield and low cost.

Horng et al. reported a mirror-substrate (MS) AlGaInP/metal/SiO₂/Si light emitting diode fabricated by wafer-fused technology [Appl. Phys Lett. Vol. 75, No. 20, 3054 (1999); AlGaInP light-emitting diodes with mirror substrates fabricated by wafer bonding]. They used the AuBe/Au as the adhesive to bond the Si substrate and light emitting diode epilayers. However, the luminous intensity of these MS AlGaInP light emitting diode is about 90 mcd with 20 mA injection current, and is still 40% lower than that of TS AlGaInP light emitting diode. Thus, this type of light emitting diode chip can hardly have a satisfying brightness.

### SUMMARY OF THE INVENTION

As described above, the conventional light emitting diode has many disadvantages. Therefore, the present invention provides a light emitting diode structure and a method for making the same to overcome the conventional disadvantages.

It is therefore an object of this invention to provide a structure and a method for fabricating a light emitting diode. In this way, the problem of an emitting light absorbed by a substrate can be resolved, and the brightness of the light emitting diode can be enhanced by using a bragg reflector structure of high reflectivity.

It is therefore another object of this invention to provide a structure and a method for fabricating a light emitting diode. The present invention provides a bragg reflector structure of high reflectivity to reflect the light generated from the light emitting diode, and the bragg reflector structure is manufactured by forming a high aluminum-contained AlGaAs/AlGaInP layer or a high-aluminum contained AlGaAs/low-aluminum contained AlGaInP layer on the substrate before the vertically-stacked epitaxial structure of the light emitting diode is formed. Due to the higher oxidation ability of the high aluminum contained AlGaAs layer and the lower refraction index of high-aluminum contained AlGaAs layer after the oxidization, the wavelength reflected by the bragg reflector layer can not only enhance the reflectivity but also coverwider spectrum.

It is therefore another object of this invention to provide a structure and a method for fabricating a light emitting diode. Since the oxidized AlGaAs layer is an electrical insulator, the electrodes are formed on the same side of the light emitting diode. In this way, the internal resistance can be decreased, and the electro-optics transferring rate can be increased.

It is therefore another object of this invention to provide a structure and a method for fabricating a light emitting diode. In this way, the light emitting diode has higher brightness than the conventional light emitting diode.

In accordance with all aspects of this invention, the invention provides a structure of a light emitting diode, comprising: a bragg reflector layer located on a substrate, an LED epitaxial structure covering the bragg reflector layer, the LED epitaxial structure comprising an n-type III-V compound semiconductor layer, an illuminating active layer, and a p-type III-V compound semiconductor layer, a first electrode formed on the exposed n-type III-V compound semiconductor layer, and a second electrode formed on the exposed p-type III-V compound semiconductor layer.

In accordance with all aspects of this invention, this invention provides a method manufacturing a light emitting diode, comprising the steps of: forming a bragg reflector layer covering a substrate, forming an epitaxial structure covering the bragg reflector layer, the epitaxial structure comprising an n-type III-V compound semiconductor layer, an illuminating active layer, and a p-type III-V compound semiconductor layer, etching the LED epitaxial structure to expose a portion of the n-type III-V compound semiconductor layer, conducting a treatment for completely oxidizing a high-aluminum contained layer of the bragg reflector layer thereby forming the bragg reflector layer having the features of high reflectivity and current insulation, forming a first electrode on the exposed n-type III-V compound semiconductor layer, and forming a second electrode on the exposed p-type III-V compound semiconductor layer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic diagram showing a conventional structure of light emitting diode;

FIG. 2 is an epitaxial structure of a light emitting diode structure of the present invention;

FIGS. 3 is the structure of light emitting diode of the present invention;

FIG. 4 shows the relationship between the reflectivity and the injected wavelength onto the bragg reflector layer according to the present invention and prior art; and

FIG. 5 shows the relationship between the reflectivity and the pair number of the bragg reflector layer according to the present invention and prior art.

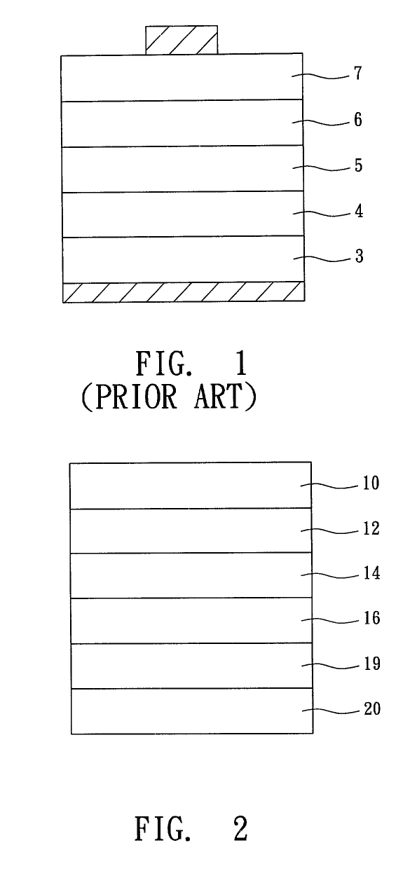

### DETAILED DESCRIPTION OF THE PREFERRED EMBODIMENT

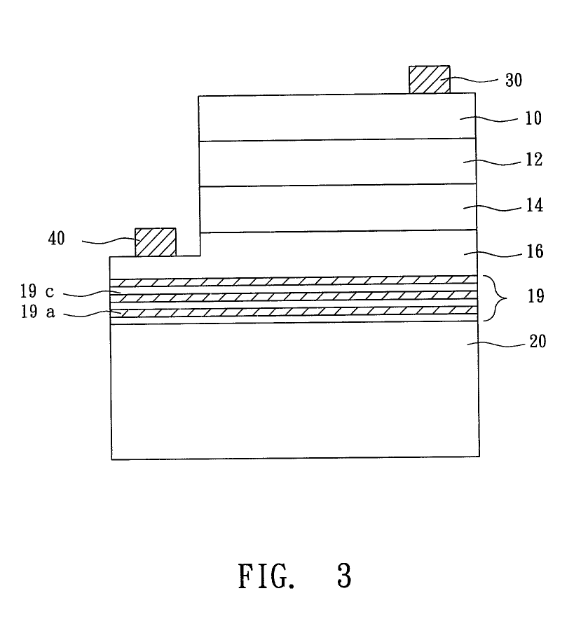

The present invention discloses a light emitting diode structure and a method of making the same, and is described in details as follows with the reference of FIGS. 2 to 5.

Referring to FIG. 2, the epitaxial structure of high brightness light emitting diode of the present invention is stacked in sequence by an n-type GaAs substrate 20, a bragg reflector layer 19, an n-type (AlₓGa₁₋ₓ)_{0.5}In_{0.5}P lower cladding layer 16, a (AlₓGa₁₋ₓ)_{0.5}In_{0.5}P active layer 14 with a Al dosage of about 0≦×≦0.45, a p-type (AlₓGa₁₋ₓ)_{0.5}In_{0.5}P upper cladding layer 12 and a p-type ohmic contact layer 10. The p-type ohmic contact layer 10 may be made of the materials with energy gap higher than the active layer, such as AlGaInP, AlGaAs, or GaPAs, or the materials with energy gap lower than the active layer but with thin thickness, for example, the preferred thickness of the p-type ohmic contact layer 10 with GaAs material is about less than 1000 angstrom for decreasing the light absorption by the p-type ohmic contact layer. A portion of light generated by the active layer is emitted from the p-type ohmic contact layer, so that the ohmic contact layer's energy gap should be higher than that of the active layer so as to avoid the light absorption. But the semiconductor with higher energy gap is not easy to form a high dopent concentration, so that the characteristic of the ohmic contact is poor. The semiconductor with lower energy gap has an advantage of easily forming a high dopent concentration, but has the intention of absorbing light, so that the thickness should not be too thick.

In the above description, the composition ratio of the compound, such as, (AlₓGa₁₋₅)_{0.5}In_{0.5}P is merely stated as a preferred example, but not used for limiting the scope of the present invention, wherein, for (AlGa)ₓIn_{y}P, it is just required that X>0 and Y<1, and the values of X and Y do not have to be equal to 0.5, and further, the present invention can also utilize other materials. In addition, the structure of the AlGaInP active layer 14 of the invention can be a DH structure or a multiple quantum well (MQW). The DH structure comprises the n-type (AlₓGa₁₋ₓ)_{0.5}In_{0.5}P lower cladding layer 16 with a Al dosage of about 0.5≦×≦1, a (AlₓGa₁₋ₓ)_{0.5}In_{0.5}P active layer 14 and a p-type (AlₓGa₁₋ₓ)_{0.5}In_{0.5}P upper cladding layer 12 with a Al dosage of about 0.5≦×≦1, such as shown in FIG. 2, wherein the thicknesses of the cladding layers 12 and 16 are respectively between 0.5 and 3 μm, and the active layer 14 is between 0.5 and 1.5 μm thick.

According to the embodiment of the present invention, the bragg reflector layer 19 is sandwiched between the n-type GaAs substrate 20 and the lower cladding layer 16. The bragg reflector layer 19 comprises a plurality of pairs of easily oxidized and stacked structure of high aluminum-contained AlGaAs/AlGaInP layers or high aluminum-contained AlGaAs/AlInP layers or high aluminum contain AlGaAs/low aluminum-contained AlGaAs layers. The high aluminum-contained AlGaAs/AlInP is partially oxidized to form an insulator with low refraction index, and the bragg reflector, which is formed as described above, can reflect the emitting light generated by the active layer 14. The thickness of each layer of high reflectivity bragg reflector layer can be designed to be equal to λ/4n, wherein the λ is the wavelength of the emitting light of the light emitting diode, and the n is the refractive index.

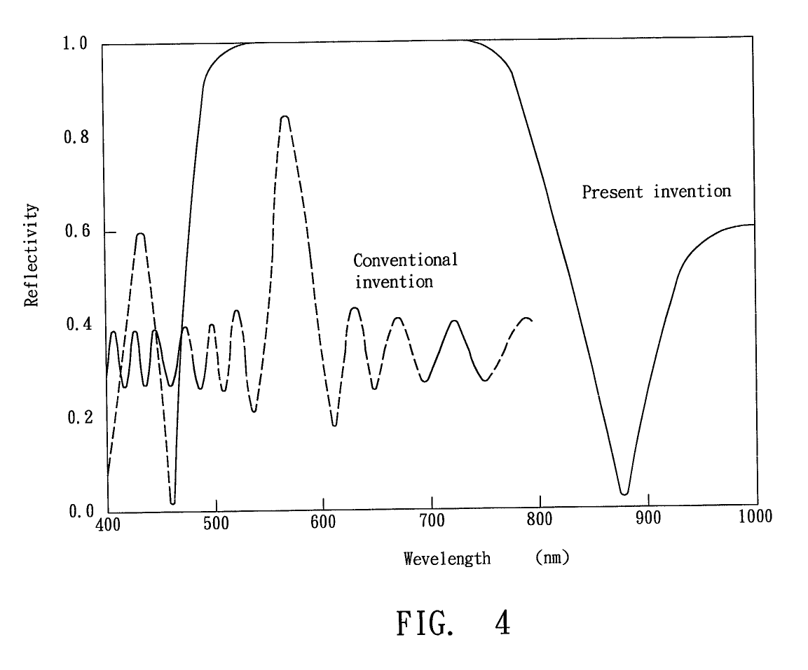

Referring to FIG. 3, which depicts the structure of the present invention of the light emitting diode. In this embodiment, the bragg reflector layer 19 comprises three pairs of high aluminum-contained AlGaAs/AlGaInP layer 19c, wherein the number of pairs is not limited thereto. Due to the higher oxidation ability of the high aluminum-contained AlGaAs, a treatment of oxidation is processed for high aluminum-contained AlGaAs layer 19c from outside to inside. By flowing steam into the LED and controlling the temperature between 300 and 800 degree. C, an AlₓO_{y} layer 19a is formed. The oxidation rate of the high aluminum-contained AlGaAs is directly proportional to the reacting temperature and the content of aluminum. The present invention controls the content of aluminum between about 80% and about 100%, and the reacting temperature above 300 degree. C, thereby finishing the oxidation process within an acceptable range of time.

Thereafter, an etching step is utilized to etch out a portion of the p-type ohmic contact layer 10, upper cladding layer 12, active layer 14, and lower cladding layer 16, thereby exposing a portion of the lower cladding layer 16. Then, an n-electrode 40 is formed on the lower cladding layer 16, and a p-electrode 30 is formed on the ohmic contact layer 10.

According to the structure of the light emitting diode, the electrodes of LED are formed on the same side of the diode. The current only run through the active layer 14, and the cladding layers 12 and 16. Thus, the internal resistance of the light emitting diode can be decreased and the electro-optics transferring rate can be increased.

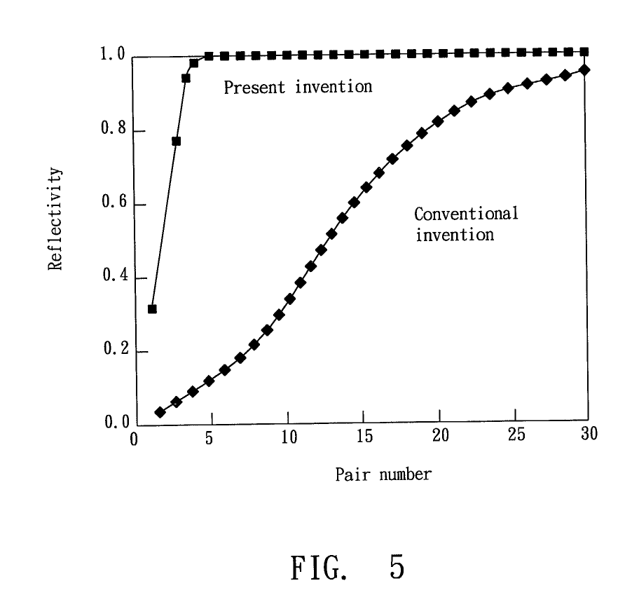

Referring to FIG. 4, after the treatment of oxidation, refraction index of the AlₓO_{y} is 1.6, which is different from the reflective index of hardly oxidized semiconductor material such as low aluminum-contained AlGaAs or AlGaInP of about higher than 3. Consequently, the wavelength reflected by the bragg reflector layer 19 can cover a wider spectrum between 500˜800 nm, as shown in FIG. 3. So that, the bragg reflector layer 19 can reflect most of the visible spectrum with a reflectivity closed to 100%. Accordingly, the brightness of LED is significantly enhanced. Although the bragg reflector layer 19 of this embodiment is sandwiched between the n-type GaAs substrate 20 and the lower cladding layer 16, yet the present invention is not limited thereto, the bragg reflector layer 19 of the present invention can also be located in the lower cladding layer 16 and still achieve the same effect.

As shown in FIG. 4, a comparison between the bragg reflector layer of the present invention and prior art is showed. The reflectivity of the conventional bragg reflector layer, which comprises an AlGaInP/AlInP layer, is 80% only in the wavelength regions of 550˜600 nm, and is poor in the other regions. On the other hand, the reflectivity of the bragg reflector layer of the present invention is almost 100% in the wavelength region of 500˜800 nm. Therefore, the bragg reflector layer of the present invention has a high reflectivity.

Furthermore, please refer to FIG. 5, it illustrates the reflectivity achieved by the pair number of oxidized high aluminum-contained AlGaAs/AlGaInP layers or oxidized high aluminum-contained AlGaAs/low aluminum-contained AlGaAs layers of the bragg reflector layer in the present invention, and those of AlGaInP/AlInP layers of the bragg reflector layer in the prior art. Apparently, in the present invention, 4 pairs of oxidized high aluminum-contained AlGaAs/AlGaInP layers or oxidized high aluminum-contained AlGaAs/low aluminum-contained AlGaAs layers of the bragg reflector layer can obtain the high reflectivity of about 100%. In contrast, 20 pairs of AlGaInP/AlInP layers of the conventional bragg reflector layer can only obtain the poor reflectivity of 80%. Therefore, the bragg reflector layer structure of the present invention is simpler, and the reflectivity thereof is higher than that of the conventional bragg reflector layer.

Since the bragg reflector layer comprising Al_{X}O_{Y} layer can reflect almost all the visible spectrum, the high reflectivity bragg reflector layer of the present invention is suitable for use in all light emitting diodes.

It is therefore an advantage of this invention to provide a structure and a method for fabricating a light emitting diode, to prevent an emitting light from being absorbed by a substrate, thereby enhancing the brightness of light emitting diode by using a high reflectivity bragg reflector layer.

It is therefore another advantage of this invention to provide a structure and a method for fabricating a light emitting diode. The present invention provides a high reflectivity bragg reflector structure to reflect the light generated from the light emitting diode, which is an oxidized high aluminum-contained AlGaAs/AlGaInP layer or an oxidized high aluminum-contained AlGaAs/low aluminum-contained AlGaAs, formed on the substrate before the vertically-stacked epitaxial structure of the light emitting diode is formed. Due to the higher oxidation ability of the high aluminum-contained AlGaAs layer and the lower refraction index of the oxidized Al_{X}O_{Y} layer, the wavelength reflected by the bragg reflector layer can cover almost all the visible spectrum.

It is therefore another advantage of this invention to provide a structure and a method for fabricating a light emitting diode. According to the electrical insulation function of the oxidized AlGaAs layer, the electrodes are formed on the same side of the light emitting diode. In this way, the internal resistance of LED can be decreased, and the electro-optics transferring rate can be increased.

It is therefore another advantage of this invention to provide a structure and a method for fabricating a light emitting diode. In this way, the light emitting diode has higher light output than the conventional light emitting diode.

While the preferred embodiment of the invention has been illustrated and described, it will be appreciated that various changes can be made therein without departing from the spirit and scope of the invention.

What is claimed is:

1. A structure of a light emitting diode (LED), comprising:
a substrate;
a bragg reflector layer located on said substrate;
an LED epitaxial structure located on said bragg reflector layer, wherein said LED epitaxial structure comprises an n-type III-V compound semiconductor layer, an illuminating active layer, and a p-type III-V compound semiconductor layer;
a first electrode located on an exposed portion of said n-type III-V compound semiconductor layer; and
a second electrode located on an exposed portion of said p-type III-V compound semiconductor layer.

2. The structure according to claim 1, wherein said bragg reflector layer comprises a plurality of oxidizable semiconductor layers and a plurality of hardly oxidized semiconductor layers stacked on each other.

3. The structure according to claim 2, wherein said plurality of hardly oxidized semiconductor layers in said bragg reflector layer are AlGaInP layers.

4. The structure according to claim 2, wherein said plurality of hardly oxidized semiconductor layers in said bragg reflector layer are AlInP layers.

5. The structure according to claim 2, wherein said plurality of hardly oxidized semiconductor layers in said bragg reflector layer are AlGaAs layers.

6. The structure according to claim 2, wherein said plurality of oxidizable layers in said bragg reflector layer are high aluminum-contained AlGaAs layers.

7. The structure according to claim 6, wherein the aluminiferous content of said high aluminum-contained AlGaAs layers are between about 80% and about 100%.

8. The structure according to claim 6, wherein a current insulating layer is formed by oxidizing said high aluminum-contained AlGaAs layers at a temperature between about 300 and about 800 degree C.

9. A method forming a light emitting diode, comprising the steps of:
providing a substrate;
forming a bragg reflector layer on said substrate;
forming an LED epitaxial structure on said bragg reflector layer, wherein said LED epitaxial structure comprises an n-type III-V compound semiconductor layer, an illuminating active layer, and a p-type III-V compound semiconductor layer;
etching said LED epitaxial structure for exposing a portion of said n-type III-V compound semiconductor layer;
conducting a treatment for completely oxidizing a high aluminum-contained layer of said bragg reflector layer for forming a high reflectivity and current insulating layer in said bragg reflector layer;
forming a first electrode on said exposed n-type III-V compound semiconductor layer; and
forming a second electrode on said p-type III-V compound semiconductor layer.

10. The method according to claim 9, wherein said bragg reflector layer comprises a plurality of oxidizable semiconductor layers and a plurality of hardly oxidized semiconductor layers stacked on each other.

11. The method according to claim 10, wherein said plurality of hardly oxidized semiconductor layers in said bragg reflector layer are AlGaInP layers.

12. The method according to claim 10, wherein said plurality of hardly oxidized semiconductor layers are AlInP layers.

13. The method according to claim 10, wherein said plurality of hardly oxidized semiconductor layers in said bragg reflector layer are AlGaAs layers.

14. The method according to claim 10, wherein said plurality of oxidizable layers in said bragg reflector layer are high aluminum-contained AlGaAs layers.

15. The method according to claim 14, wherein the aluminiferous content of said high aluminum-contained AlGaAs layers are between about 80% and about 100%.

16. The method according to claim 14, wherein a current insulating layer is formed by oxidizing said high aluminum-contained AlGaAs layers at a temperature between about 300 and about 800 degree C.
